(19) United States
(12) Patent Application Publication
(10) Pub. No.: US 2026/0182289 A1
(43) Pub. Date: Jun. 25, 2026

(54) CHIP PRODUCTION METHOD AND CUTTING DEVICE

(71) Applicant: DISCO CORPORATION, Tokyo (JP)

(72) Inventors: Suguru HIRAIWA, Tokyo (JP); Takumi KOHEI, Tokyo (JP)

(21) Appl. No.: 19/430,648

(22) Filed: Dec. 23, 2025

(30) Foreign Application Priority Data
Dec. 25, 2024 (JP) 2024-228648
Oct. 29, 2025 (JP) 2025-182522

(51) Int. Cl. H10P 54/50; H10P 58/00; H10P 72/70

(52) U.S. Cl. CPC H10P 54/52; H10P 58/20; H10P 72/7402

(57) ABSTRACT

A chip production method by dividing a substrate having a first surface and a second surface along plural planned dividing lines set in a lattice pattern on the substrate, includes: holding the second surface of the substrate by a holding table such that the first surface of the substrate is exposed; cutting the substrate along each of the planned dividing lines by rotating a cutting blade in a down-cut direction from the first surface toward the second surface while vibrating the cutting blade at a vibration frequency in an ultrasonic band, thereby forming a cutting groove on the first surface that does not reach the second surface; and cutting an uncut portion of the planned dividing line where the cutting groove is formed by rotating the cutting blade in an up-cut direction from the second surface toward the first surface, after the forming of the cutting groove.

### CROSS-REFERENCE TO RELATED APPLICATIONS

This application is based on and claims priority under 35 USC 119 from Japanese Patent Application No. 2024-228648 filed on Dec. 25, 2024 and Japanese Patent Application No. 2025-182522 filed on Oct. 29, 2025, the contents of which are incorporated herein by reference.

### TECHNICAL FIELD

The present disclosure relates to a chip production method for producing a plurality of chips by dividing a substrate, and a cutting device for dividing a substrate.

### BACKGROUND ART

As a method of dividing a plurality of devices formed on a front surface of a substrate such as a semiconductor wafer into chips, a method is known in which the substrate is cut with a cutting blade along planned dividing lines (streets) of the substrate.

When cutting with a cutting blade, chipping (flaws) may occur on a cutting end surface of the substrate. In order to reduce such chipping, for example, Patent Literature 1 describes a technique in which a cutting blade is used to cut a substrate from one surface thereof to form a cutting groove that does not reach the other surface, and then the remaining portion is cut from the other surface to divide the substrate.

Patent Literature 1: JP2013-58653A

### SUMMARY OF INVENTION

Incidentally, when a substrate having cleavability that easily cleaves along a specific plane, such as β-gallium oxide (β-Ga₂O₃), is cut with a cutting blade, a method for reducing a cutting feed speed may be used to prevent chipping due to cleavage. However, this method has a problem in that the cutting time is longer.

An object of the present disclosure is to provide a chip production method and a cutting device capable of reducing cutting time while reducing chipping.

The present disclosure provides a chip production method for producing a plurality of chips by dividing a substrate having a first surface and a second surface opposite to the first surface along a plurality of planned dividing lines set in a lattice pattern, the chip production method including:
a holding step of holding the second surface of the substrate by a holding table such that the first surface of the substrate is exposed;
a cutting groove forming step of cutting the substrate along each of the planned dividing lines by rotating a cutting blade in a down-cut direction from the first surface toward the second surface while vibrating the cutting blade at a vibration frequency in an ultrasonic band, thereby forming a cutting groove on the first surface that does not reach the second surface; and
a first dividing step of cutting an uncut portion of the planned dividing line where the cutting groove is formed by rotating the cutting blade in an up-cut direction from the second surface toward the first surface, after the cutting groove forming step.

The present disclosure also provides a cutting device for producing a plurality of chips by dividing a substrate having a first surface and a second surface opposite to the first surface along a plurality of planned dividing lines set in a lattice pattern, the cutting device including:
a holding table configured to hold the second surface of the substrate such that the first surface of the substrate is exposed;
a cutting unit including a cutting blade configured to relatively move along the planned dividing lines to cut the substrate; and
a controller configured to control the holding table and the cutting unit, in which
the cutting unit further includes an ultrasonic vibrator capable of vibrating the cutting blade at a vibration frequency in an ultrasonic band, and
the controller executes a process of
   cutting the substrate along each of the planned dividing lines by rotating the cutting blade in a down-cut direction from the first surface toward the second surface while vibrating the cutting blade at a vibration frequency in an ultrasonic band, thereby forming a cutting groove on the first surface that does not reach the second surface, and
   cutting an uncut portion of the planned dividing line where the cutting groove is formed by rotating the cutting blade in an up-cut direction from the second surface toward the first surface, after the cutting groove is formed.

### BRIEF DESCRIPTION OF DRAWINGS

FIG. 1 is a perspective view of a substrate.

FIG. 2 is a front view of the substrate illustrating each surface of the substrate.

FIG. 3 is a perspective view of a substrate unit.

FIG. 4 is a perspective view of a cutting device according to an embodiment of the present disclosure.

FIG. 5 is an exploded perspective view of a cutting unit of the cutting device.

FIG. 6 is a partial cross-sectional side view of the cutting unit.

FIG. 7 is a perspective view illustrating how the substrate is cut by the cutting unit.

FIG. 8 is a flowchart of a chip production method.

FIG. 9 is a diagram illustrating a holding step.

FIGS. 10A and 10B are diagrams illustrating a cutting groove forming step.

FIG. 11 is a diagram illustrating a cutting groove and a fractured layer formed in the cutting groove forming step.

FIGS. 12A and 12B are diagrams illustrating a first dividing step.

FIG. 13 is a partial cross-sectional view of a substrate after the first dividing step.

FIGS. 14A and 14B are diagrams illustrating a second dividing step.

FIG. 15 is a top view of a plurality of chips produced through the first dividing step and the second dividing step.

FIG. 16 is a top view of a cutting device 20 according to a modification in which two cutting units 40 are provided.

FIG. 17 is a side view of the cutting device 20 according to the modification.

### DESCRIPTION OF EMBODIMENTS

Hereinafter, an embodiment of a chip production method and a cutting device of the present disclosure will be described with reference to the accompanying drawings.

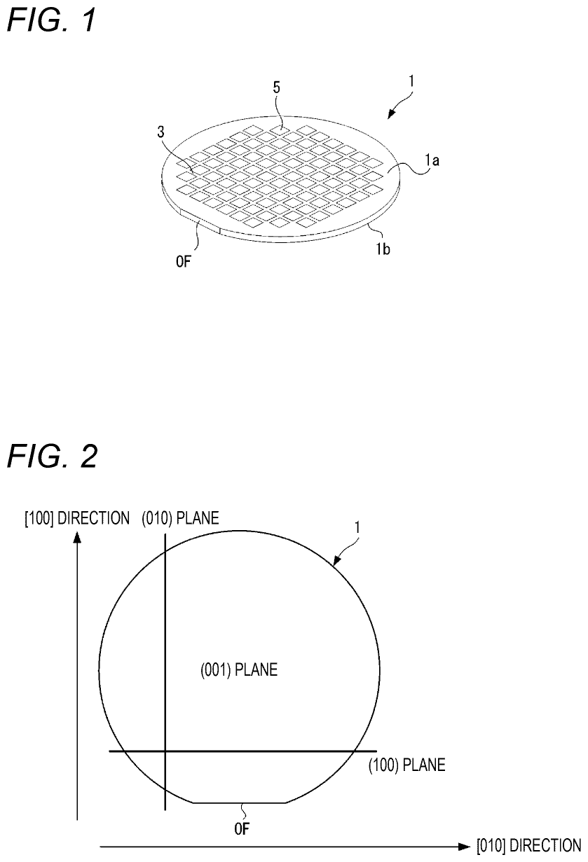

The chip production method of the present disclosure is a method for producing a plurality of chips by dividing a substrate. First, the substrate will be described with reference to FIGS. 1 and 2.

### Substrate

FIG. 1 is a perspective view of a substrate 1. FIG. 2 is a front view of the substrate 1 illustrating each surface of the substrate 1. The substrate 1 is a wafer having a disk shape and is made of, for example, a semiconductor material. The substrate 1 is, for example, a gallium oxide (Ga₂O₃) substrate, more specifically, a β-gallium oxide (β-Ga₂O₃) substrate.

As illustrated in FIG. 1, the substrate 1 has a front surface 1a and a back surface 1b opposite to the front surface 1a. An orientation flat OF indicating a crystal orientation is formed in an outer peripheral portion of the substrate 1.

As illustrated in FIG. 2, in the substrate 1 made of β-gallium oxide having a monoclinic structure, the front surface 1a is a (001) plane, a plane parallel to a direction in which the orientation flat OF extends is a (100) plane, and a plane perpendicular to the direction in which the orientation flat OF extends is a (010) plane. A direction perpendicular to the (010) plane is a [010] direction, and a direction perpendicular to the (100) plane is a [100] direction. In the following description, equivalent planes may be collectively represented using curly brackets { }, and equivalent directions may be collectively represented using angle brackets < >.

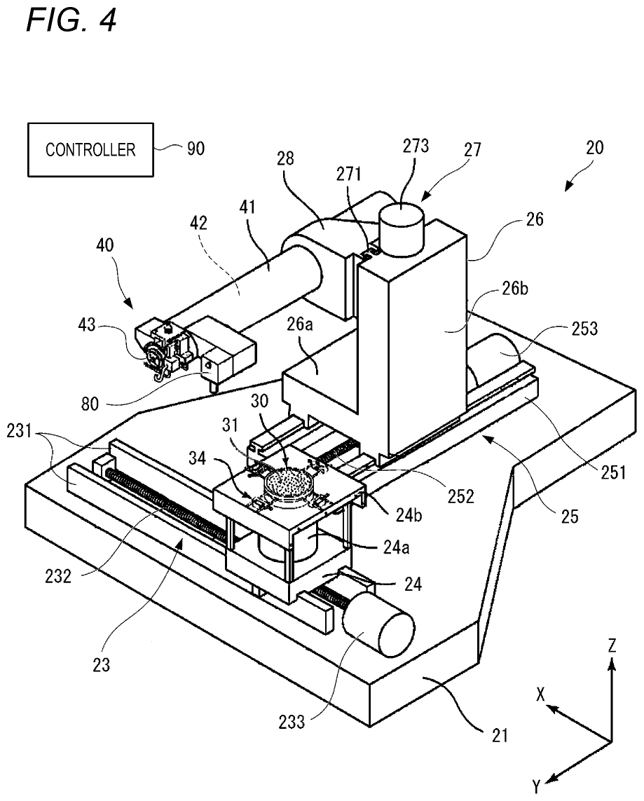

In the substrate 1, the (100) plane and the (001) plane are cleavage planes. Therefore, when a cutting device 20 (see FIG. 4), which will be described later, divides the substrate 1 along the (010) plane perpendicular to these cleavage planes, the substrate 1 is prone to cleavage along the (100) plane and the (001) plane, and chipping is likely to occur on a cutting end surface.

Returning to FIG. 1, a plurality of planned dividing lines (also referred to as streets) 3 are set in a lattice pattern on the front surface 1a. The planned dividing lines 3 in a lattice pattern include a plurality of planned dividing lines 3 extending in the [100] direction and a plurality of planned dividing lines 3 extending in the [010] direction. In each of rectangular regions defined by the plurality of planned dividing lines 3, a device 5 such as a metal-oxide-semiconductor field-effect transistor (MOSFET) or an insulated gate bipolar transistor (IGBT) is provided.

The type, number, shape, structure, size, arrangement, and the like of the device 5 are not particularly limited. On the front surface 1a side of the substrate 1, a key pattern (not illustrated) having a predetermined shape is formed, which is used to specify the position of the planned dividing lines 3.

### Substrate Unit

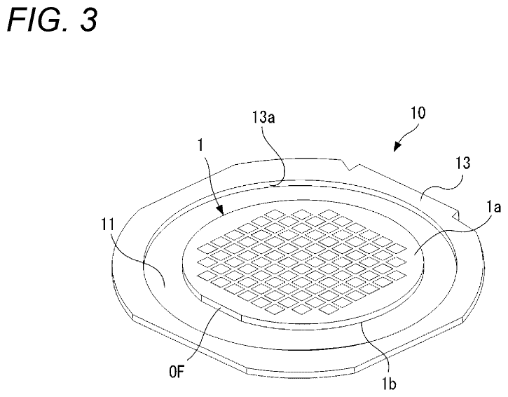

FIG. 3 is a perspective view of a substrate unit 10. When the substrate 1 is processed, the substrate 1 is integrated with a metal annular frame 13 by a circular tape (dicing tape) 11 made of a material such as resin. That is, the substrate unit 10 is configured by integrating the substrate 1 with the frame 13 via the tape 11.

The frame 13 has a circular opening 13a that is larger in diameter than the substrate 1. In the substrate unit 10, the tape 11 is attached to the back surface 1b of the substrate 1, which is disposed in the opening 13a such that the front surface 1a is exposed, and to one surface of the frame 13.

The tape 11 has a diameter larger than that of the opening 13a of the frame 13. The tape 11 is, for example, a resin film in which a glue layer (adhesive layer) is laminated on a base material layer made of resin, and is a substantially transparent film that substantially transmits visible light and ultraviolet light. The base material layer is made of resin such as polyolefin (PO), polyvinyl chloride (PVC), or polyethylene terephthalate (PET), and the adhesive layer is made of resin such as acrylic resin or epoxy resin. The adhesive layer is, for example, ultraviolet-curable resin, and is provided on the entire surface of the base material layer. The ultraviolet-curable resin has a relatively strong adhesive strength before being irradiated with ultraviolet rays, but once irradiated with ultraviolet rays (UV), the adhesive strength decreases.

The tape 11 may not have an adhesive layer at least in a region that comes into contact with the substrate 1. In this case, the substrate 1 is attached to the tape 11 by thermocompression bonding or the like without using an adhesive layer.

### Cutting Device

Next, a cutting device according to an embodiment of the present disclosure will be described with reference to FIGS. 4 to 7.

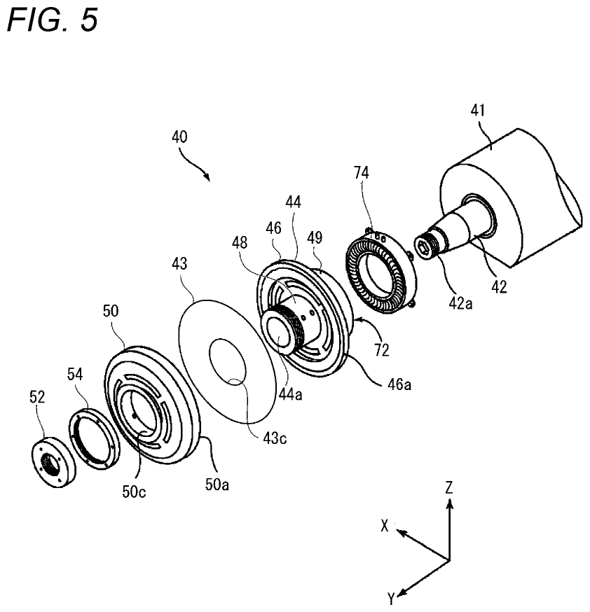

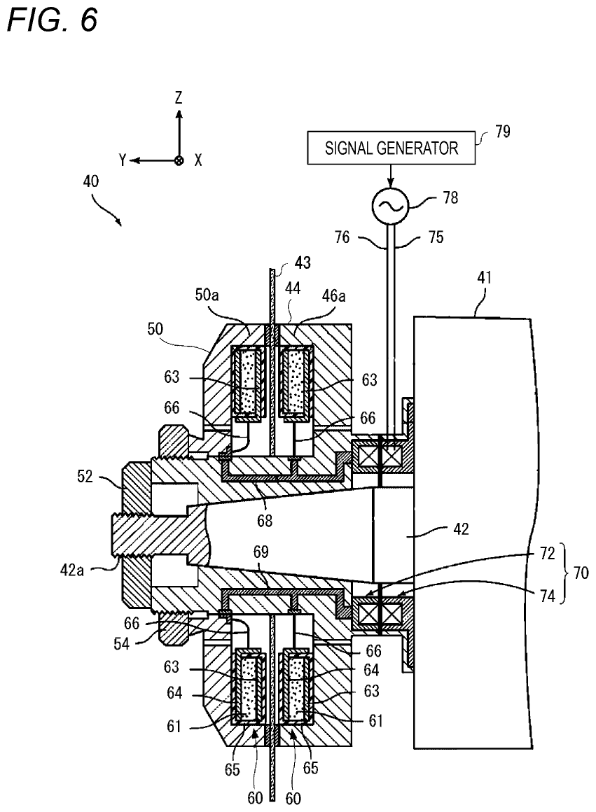

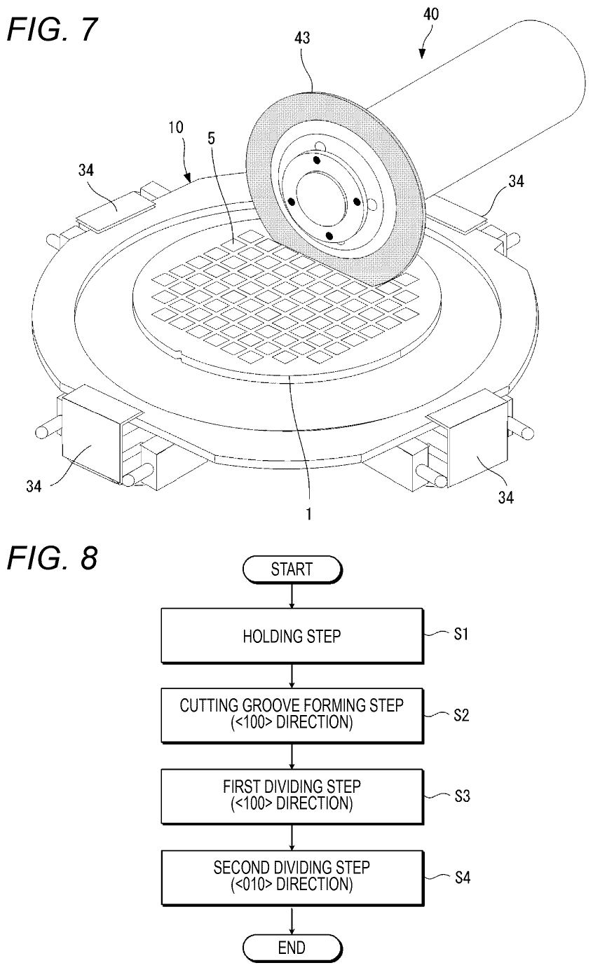

FIG. 4 is a perspective view of the cutting device 20 according to an embodiment of the present disclosure. FIG. 5 is an exploded perspective view of a cutting unit 40 of the cutting device 20. FIG. 6 is a partial cross-sectional side view of the cutting unit 40. FIG. 7 is a perspective view illustrating how the substrate 1 is cut by the cutting unit 40.

After being transported to the cutting device 20, the substrate unit 10 is cut along each planned dividing line 3. An X-axis direction (processing feed direction), a Y-axis direction (indexing feed direction), and a Z-axis direction (height direction, up-down direction, cutting feed direction) illustrated in FIG. 4 are orthogonal to each other.

The cutting device 20 includes a base 21 that supports each component, a chuck table (holding table) 30 that holds the substrate 1, the cutting unit 40 that cuts the substrate 1 held by the chuck table 30, and a controller 90 that controls the chuck table 30 and the cutting unit 40.

A ball screw type X-axis direction moving unit 23 is provided on an upper surface of the base 21. The X-axis direction moving unit 23 includes a pair of guide rails 231 disposed substantially parallel to the X-axis direction.

A moving table 24 is slidably mounted on the pair of guide rails 231. A nut portion (not illustrated) is provided on a back surface side (lower surface side) of the moving table 24, and a screw shaft 232 disposed parallel to the X-axis direction is rotatably coupled to the nut portion.

A drive source 233 such as a stepping motor is connected to one end of the screw shaft 232. By rotating the screw shaft 232 with the drive source 233, the moving table 24 moves in the X-axis direction. A cylindrical support base 24a is provided substantially at the center of an upper surface side of the moving table 24.

A rectangular table cover 24b is provided above the support base 24a, and the chuck table 30 is provided on an upper surface side of the table cover 24b. A drive source such as a motor is provided inside the support base 24a, and when the drive source is operated, the chuck table 30 rotates about a rotation axis substantially parallel to the Z-axis direction.

The chuck table 30 has a disk-shaped frame body made of a metal material such as stainless steel. A disk-shaped recess having a diameter smaller than that of the frame body is formed in an upper portion of the frame body. A disk-shaped porous plate made of porous ceramic is fixed to the recess of the frame body.

A negative pressure is transmitted to the porous plate from a suction source (not illustrated) such as a vacuum pump through a predetermined flow path (not illustrated) formed in the frame body. An upper surface of the frame body and an upper surface of the porous plate are substantially flush with each other and constitute a substantially flat holding surface 31.

The holding surface 31 is disposed substantially parallel to an XY plane. When the substrate unit 10 is placed on the chuck table 30, the substrate 1 is held under suction on the holding surface 31 via the tape 11.

Around the chuck table 30, a plurality of (four in the illustrated example) clamp units 34 are disposed at equal intervals along a circumferential direction of the chuck table 30. The clamp units 34 fix the frame 13 of the substrate unit 10 placed on the chuck table 30.

A ball screw type Y-axis direction moving unit 25 is further provided on the upper surface of the base 21. The Y-axis direction moving unit 25 includes a pair of guide rails 251 disposed substantially parallel to the Y-axis direction.

A moving block 26 is slidably mounted on the pair of guide rails 251. The moving block 26 has a horizontal plate portion 26a adjacent to the pair of guide rails 251. A nut portion (not illustrated) is provided on a lower surface side of the horizontal plate portion 26a.

A screw shaft 252 disposed substantially parallel to the Y-axis direction is rotatably coupled to the nut portion. A drive source 253 such as a stepping motor is connected to one end of the screw shaft 252. When the screw shaft 252 is rotated by the drive source 253, the moving block 26 moves in the Y-axis direction.

A vertical plate portion 26b is provided on an upper surface of the horizontal plate portion 26a. A Z-axis direction moving unit 27 is provided on one side surface of the vertical plate portion 26b that is substantially parallel to a YZ surface. The Z-axis direction moving unit 27 includes a pair of guide rails 271 disposed substantially parallel to the Z-axis direction. In FIG. 4, only one guide rail 271 is illustrated.

A holder 28 is slidably mounted on the pair of guide rails 271. A nut portion (not illustrated) is provided on a back surface side of the holder 28, and a screw shaft (not illustrated) disposed substantially parallel to the Z-axis direction is rotatably coupled to the nut portion.

A drive source 273 such as a stepping motor is connected to an upper end portion of the screw shaft. When the screw shaft is rotated by the drive source 273, the holder 28 moves in the Z-axis direction.

The cutting unit 40 includes a spindle housing 41 fixed to the holder 28, a spindle 42, a cutting blade 43 mounted on a tip end of the spindle 42, the Y-axis direction moving unit 25, and the above Z-axis direction moving unit 27.

The spindle housing 41 has a cylindrical shape, and a longitudinal portion thereof is disposed substantially parallel to the Y-axis direction. A tip end portion of the spindle housing 41 is open, from which a tip end portion 42a of the spindle 42 protrudes.

An imaging device 80 capable of capturing an image of the substrate 1 is provided on the side of the spindle housing 41. Although not illustrated, the imaging device 80 is, for example, an infrared camera capable of capturing an image of the substrate 1 with infrared rays, and includes one or more lenses, a light source such as a light emitting diode (LED) that emits infrared rays, and a solid-state imaging element (image sensor) capable of photoelectrically converting infrared rays.

The spindle 42 has a cylindrical shape, and a longitudinal portion thereof is disposed substantially parallel to the Y-axis direction. The spindle 42 is rotatably accommodated in the spindle housing 41. A rotary drive source such as a motor is provided in a vicinity of a base end portion of the spindle 42.

As illustrated in FIG. 5, the tip end portion 42a of the spindle 42 protrudes from the spindle housing 41. The cutting blade 43 is mounted on the tip end portion 42a of the spindle 42.

The cutting blade 43 is configured as a hubless (washer) blade including an annular cutting edge. The cutting blade 43 is not limited to a hubless blade, and may be a hub blade.

A circular through hole 43c is formed in the radial center of the cutting blade 43. In the cutting blade 43, abrasive grains made of diamond, cubic boron nitride (CBN), or the like are fixed by a binder such as metal, ceramic, or resin.

A male screw is formed on an outer peripheral side surface of the tip end portion 42a of the spindle 42. The tip end portion 42a of the spindle 42 is inserted into a through hole 44a of a mount 44. After the tip end portion 42a of the spindle 42 is inserted into the through hole 44a of the mount 44, the mount 44 is fixed to the spindle 42 by fastening an annular fixing nut 52 to the male screw of the tip end portion 42a of the spindle 42. The cutting blade 43 is mounted on the spindle 42 via the mount 44.

The mount 44 has a disk-shaped flange portion 46. The flange portion 46 has an annular protrusion 46a positioned on an outer peripheral portion of the flange portion 46. The protrusion 46a protrudes to one side of the flange portion 46 in a thickness direction.

A cylindrical first boss portion 48 having a diameter smaller than that of the flange portion 46 is provided on the one side of the flange portion 46 in the thickness direction. The cutting blade 43 and the like are disposed on an outer peripheral side surface of the first boss portion 48.

A male screw is formed on an outer peripheral side surface of a tip end portion of the first boss portion 48. A cylindrical second boss portion 49 having a diameter smaller than that of the flange portion 46 and larger than that of the first boss portion 48 is provided on the other side of the flange portion 46 in the thickness direction.

The through hole 44a of the mount 44 extends through the flange portion 46, the first boss portion 48, and the second boss portion 49, and is fitted to the spindle 42.

A disk-shaped pressing flange 50 is mounted on the first boss portion 48. The pressing flange 50 has a protrusion 50a having substantially the same inner diameter and outer diameter as the protrusion 46a of the flange portion 46.

The pressing flange 50 has an opening 50c in the radial center thereof. The first boss portion 48 is inserted into the through hole 43c of the cutting blade 43 and the opening 50c of the pressing flange 50 such that the cutting blade 43 is sandwiched between the protrusion 50a of the pressing flange 50 and the protrusion 46a of the flange portion 46 of the mount 44.

When the cutting blade 43 and the pressing flange 50 are disposed on the outer peripheral side surface of the first boss portion 48, an annular fixing nut 54 is fastened to the male screw of the first boss portion 48. Thus, the cutting blade 43 is sandwiched between the flange portion 46 and the pressing flange 50 and fixed to the tip end portion of the spindle 42.

The cutting unit 40 further includes an ultrasonic vibrator 60 capable of vibrating the cutting blade 43 at a vibration frequency in an ultrasonic band (for example, 20 kHz or more and 500 kHz or less). The ultrasonic vibrator 60 has an annular shape, and is provided inside the protrusion 46a of the flange portion 46 of the mount 44 in a radial direction and inside the protrusion 50a of the pressing flange 50 in a radial direction.

Each ultrasonic vibrator 60 of the present embodiment is an electrostrictive type and includes an annular piezoelectric body 61. The piezoelectric body 61 is made of, for example, piezoelectric ceramics such as barium titanate or lead zirconate titanate. A pair of electrodes 63 and 64 are provided on both annular side surfaces of the piezoelectric body 61 so as to sandwich the piezoelectric body 61. An insulating film 65 is provided to prevent electrical contact between the pair of electrodes 63 and 64 and between the pair of electrodes 63 and 64 and the flange portion 46.

Wires 68 and 69 are provided inside the mount 44, and are connected to the electrodes 63 and 64 of the ultrasonic vibrator 60 via lead wires 66, respectively. The wires 68 and 69 in the mount 44 are supplied with power from an AC power supply unit 78 via a rotary transformer 70. The rotary transformer 70 includes a power receiving unit 72 provided on the second boss portion 49 of the mount 44 and a power supply unit 74 provided on the tip end portion of the spindle housing 41.

The power receiving unit 72 includes an annular core and a coil wound around the core. One end of the coil is connected to the wire 68, and the other end of the coil is connected to the wire 69. The power supply unit 74 also includes an annular core and a coil.

The power supply unit 74 is connected to an AC power supply unit 78 such as a high-speed bipolar power supply via wires 75 and 76. A signal generator 79 that controls the frequency of the supplied AC voltage is connected to the AC power supply unit 78. When power is supplied from the AC power supply unit 78 to the pair of electrodes 63 and 64 via the rotary transformer 70, the piezoelectric body 61 vibrates so as to expand and contract along the radial direction of the mount 44 and the pressing flange 50.

Although there is a gap between the ultrasonic vibrator 60 and the cutting blade 43 in FIG. 6, the ultrasonic vibrator 60 and the cutting blade 43 are actually in contact with each other via a member (not illustrated). Due to the vibration of the piezoelectric body 61, the mount 44, the pressing flange 50, and the cutting blade 43 vibrate together.

In particular, the piezoelectric body 61 of the present embodiment vibrates not in a thickness direction of the cutting blade 43 but in a radial direction of the cutting blade 43. The amplitude of the cutting blade 43 is set to 5.0 μm, for example.

The controller 90 controls the operation of the chuck table 30, the cutting unit 40, the X-axis direction moving unit 23, the Y-axis direction moving unit 25, the Z-axis direction moving unit 27, the imaging device 80, the AC power supply unit 78, the signal generator 79, and the like.

The controller 90 is implemented by, for example, a computer including a processor (processing device) represented by a central processing unit (CPU) and a memory (storage device). The memory includes a main storage device such as a dynamic random access memory (DRAM), a static random access memory (SRAM), or a read only memory (ROM), and an auxiliary storage device such as a flash memory, a hard disk drive, or a solid state drive. The auxiliary storage device stores software including a predetermined program. The functions of the controller 90 are implemented by operating a processor or the like in accordance with the software.

### Chip Production Method

Next, a chip production method according to an embodiment of the present disclosure will be described with reference to FIGS. 8 to 15.

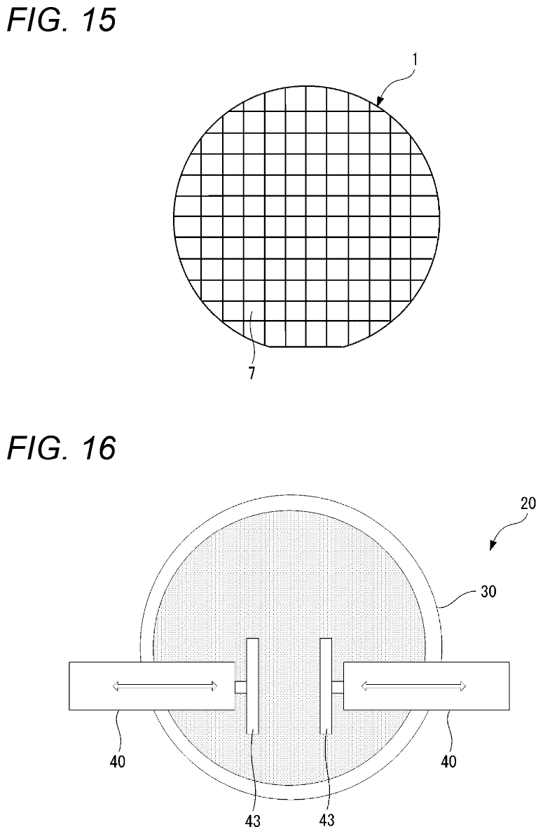

FIG. 8 is a flowchart of the chip production method. The chip production method includes a holding step S1, a cutting groove forming step S2, a first dividing step S3, and a second dividing step S4. The cutting device 20 divides the substrate 1 into a plurality of chips 7 (see FIG. 15) through each step. These steps are performed by the controller 90 controlling the chuck table 30 and the cutting unit 40.

### Holding Step S1

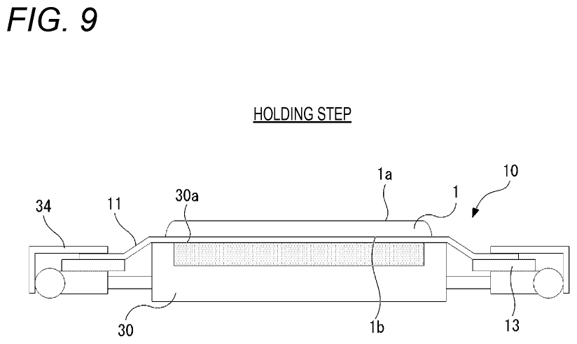

As illustrated in FIG. 9, in the holding step S1, the back surface 1b of the substrate 1 is held by the chuck table 30 such that the front surface 1a of the substrate 1 is exposed. Specifically, in the holding step S1, the substrate unit 10 is placed on the chuck table 30. The back surface 1b of the substrate 1 is held under suction on a holding surface 30a of the chuck table 30 via the tape 11, and the frame 13 is fixed by the clamp units 34.

At this time, the front surface 1a of the substrate 1 is exposed upward. In this state, the imaging device 80 captures an image of the front surface 1a, and the controller 90 obtains an image of the front surface 1a. Since a distance from the key pattern on the front surface 1a to the planned dividing line 3 is predetermined, the controller 90 detects the position of the planned dividing line 3 in the XY plane using the coordinates of the key pattern included in the image of the front surface 1a.

### Cutting Groove Forming Step S2

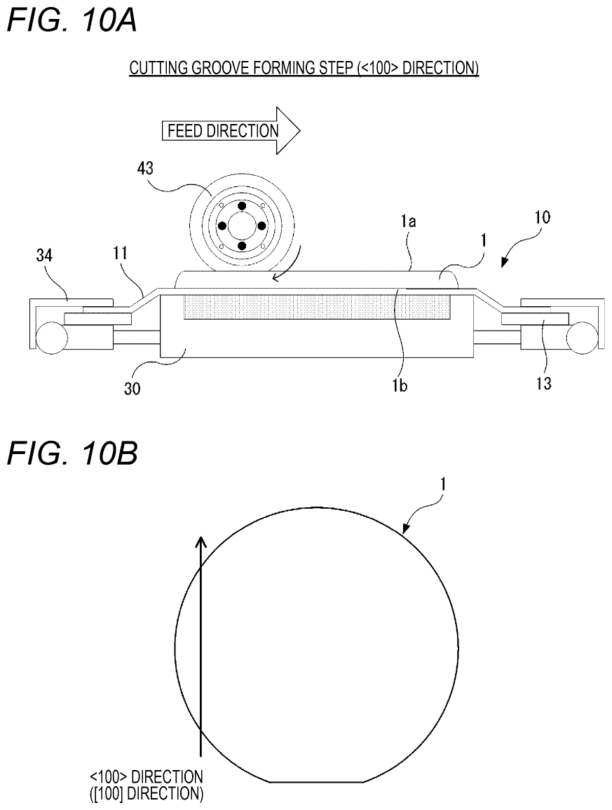

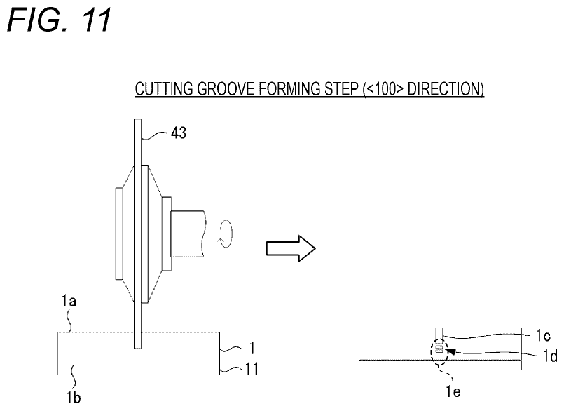

FIG. 10A illustrates the cutting groove forming step S2, and FIG. 10B illustrates a cutting direction of the substrate 1 in the cutting groove forming step S2. FIG. 11 is a diagram illustrating a cutting groove 1c and a fractured layer 1d formed in the cutting groove forming step S2.

After detecting the position of the planned dividing line 3, the controller 90 adjusts the orientation of the substrate 1 by rotating the chuck table 30 such that the planned dividing line 3 extending in a <100> direction is parallel to the X-axis direction. The <100> direction includes a [100] direction and a [−100] direction opposite to the [100] direction. The <100> direction is a direction perpendicular to the {100} plane, which is the cleavage plane of the substrate 1.

In the cutting groove forming step S2, by rotating the cutting blade 43 in a down-cut direction from the front surface 1a toward the back surface 1b while vibrating the cutting blade 43 at a vibration frequency in an ultrasonic band, the substrate 1 is cut along the planned dividing line 3 extending in the <100> direction, and a cutting groove 1c that does not reach the back surface 1b is formed in the front surface 1a.

Specifically, the controller 90 positions the cutting blade 43 on an extension line of the planned dividing line 3 extending in the <100> direction, and positions a lower end portion of the cutting blade 43 at a predetermined depth between the front surface 1a and the back surface 1b. Then, the controller 90 rotates and vibrates the cutting blade 43 while supplying a cutting liquid such as pure water, and moves the chuck table 30 along the X-axis direction. The feed speed of the cutting blade 43 relative to the substrate 1 is, for example, 6 mm/s. Thus, the cutting blade 43 cuts the substrate 1 along the planned dividing line 3 in the <100> direction. Although FIG. 10B illustrates a processing example in which the cutting blade 43 is relatively moved along the [100] direction of the <100> direction, the cutting blade 43 may be relatively moved along the [−100] direction.

When cutting is completed along one planned dividing line 3, the controller 90 moves the cutting blade 43 in the indexing feed direction and positions the cutting blade 43 on an extension line of the adjacent planned dividing line 3 to perform the cutting groove forming step S2.

In the cutting groove forming step S2, since the cutting groove 1c is formed in the substrate 1 while vibrating the cutting blade 43 at a vibration frequency in an ultrasonic band, as illustrated in FIG. 11, a fractured layer 1d is formed in an uncut portion 1e (groove bottom portion of the cutting groove 1c).

### First Dividing Step S3

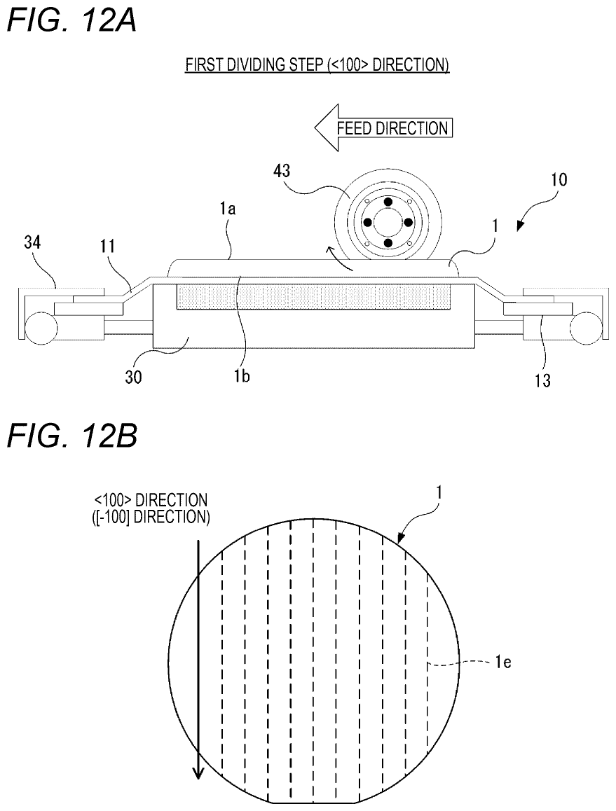

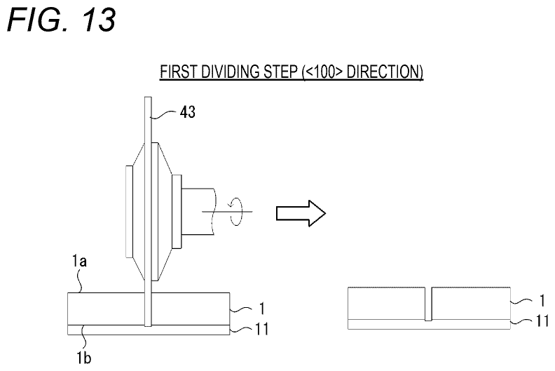

FIG. 12A is a diagram illustrating the first dividing step S3, and FIG. 12B is a diagram illustrating the cutting direction of the substrate 1. FIG. 13 is a partial cross-sectional view of the substrate 1 after the first dividing step S3.

In the first dividing step S3, after the cutting groove forming step S2, the cutting blade 43 is rotated in an up-cut direction from the back surface 1b toward the front surface 1a of the substrate 1, thereby cutting the uncut portion 1e of the planned dividing line 3 extending in the <100> direction.

Specifically, the controller 90 positions the cutting blade 43 on an extension line of the planned dividing line 3 extending in the <100> direction, and positions the lower end portion of the cutting blade 43 at a depth that exceeds the back surface 1b of the substrate 1. Then, the controller 90 rotates and vibrates the cutting blade 43 while supplying a cutting liquid, and moves the chuck table 30 along the X-axis direction. The feed speed of the cutting blade 43 relative to the substrate 1 is, for example, 3 mm/s. Thus, the cutting blade 43 cuts the substrate 1 along the planned dividing line 3 extending in the <100> direction, and cuts the uncut portion 1e of the planned dividing line 3 extending in the <100> direction to divide the substrate 1. Although FIG. 12B illustrates a processing example in which the cutting blade 43 is relatively moved along the [−100] direction of the <100> direction, the cutting blade 43 may be relatively moved along the [100] direction. Although the feed direction of the cutting blade 43 illustrated in FIGS. 12A and 12B is a direction opposite to the feed direction in the cutting groove forming step S2, the feed direction may be the same direction as the feed direction in the cutting groove forming step S2.

When cutting is completed along one planned dividing line 3, the controller 90 moves the cutting blade 43 in the indexing feed direction and positions the cutting blade 43 on an extension line of the adjacent planned dividing line 3 to perform the first dividing step S3.

In the first dividing step S3, the controller 90 positions the lower end portion of the cutting blade 43 at a depth that slightly exceeds the back surface 1b of the substrate 1, and the substrate 1 is cut so as not to penetrate the tape 11.

### Second Dividing Step S4

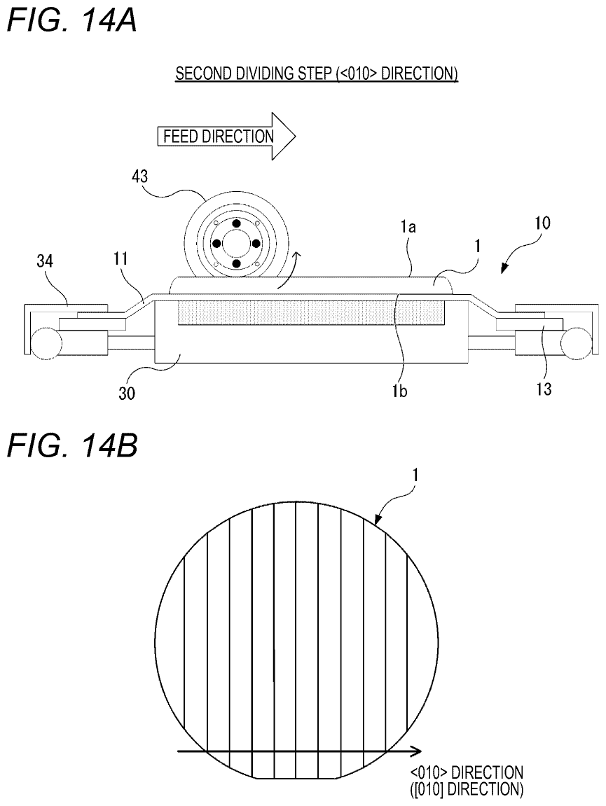

FIG. 14A is a diagram illustrating the second dividing step S4, and FIG. 14B is a diagram illustrating the cutting direction of the substrate 1.

In the second dividing step S4, after the first dividing step S3, the substrate 1 is cut along the planned dividing line 3 extending in the <010> direction of the substrate 1 by rotating the cutting blade 43 in the up-cut direction while vibrating the cutting blade 43 at a vibration frequency in an ultrasonic band. When cutting the substrate 1 in the <010> direction, the cutting blade 43 cuts the substrate 1 along the planned dividing line 3 extending in the <100> direction at once without performing the cutting groove forming step S2. The <010> direction includes the [010] direction and a [0-10] direction opposite to the [010] direction. The <010> direction is a direction parallel to the {100} plane, which is the cleavage plane of the substrate 1.

Specifically, the controller 90 adjusts the orientation of the substrate 1 by rotating the chuck table 30 by 90 degrees such that the planned dividing line 3 extending in the <010> direction is parallel to the X-axis direction. Thereafter, the controller 90 positions the cutting blade 43 on an extension line of the planned dividing line 3 extending in the <010> direction, and positions the lower end portion of the cutting blade 43 at a depth that exceeds the back surface 1b of the substrate 1. Then, the controller 90 rotates and vibrates the cutting blade 43 while supplying a cutting liquid, and moves the chuck table 30 along the X-axis direction. The feed speed of the cutting blade 43 relative to the substrate 1 is, for example, 20 mm/s. Thus, the cutting blade 43 cuts the substrate 1 along the planned dividing line 3 extending in the <010> direction.

When cutting is completed along one planned dividing line 3, the controller 90 moves the cutting blade 43 in the indexing feed direction and positions the cutting blade 43 on an extension line of the adjacent planned dividing line 3 to perform the second dividing step S4.

In the second dividing step S4, the controller 90 rotates the cutting blade 43 while operating the ultrasonic vibrator 60, but may rotate the cutting blade 43 without operating the ultrasonic vibrator 60.

By cutting the substrate 1 along the planned dividing lines 3 extending in the <100> direction and the <010> direction in this manner, a plurality of chips 7 are produced as illustrated in FIG. 15.

Next, the operation and effect of the production method of the chips 7 of the present embodiment described above will be described.

As described above, in the substrate 1 made of β-gallium oxide having a monoclinic structure, the {100} plane and the {001} plane are cleavage planes (see FIG. 2). Therefore, when the cutting blade 43 divides the substrate 1 along the {010} plane (in other words, along the <100> direction), the substrate 1 is likely to cleave along the {100} plane and the {001} plane, and chipping is likely to occur on the cutting end surface.

If the cutting blade 43 cuts the substrate 1 along the planned dividing line 3 extending in the <100> direction at once without performing the cutting groove forming step S2, it is necessary to sufficiently reduce the feed speed of the cutting blade 43 to prevent the occurrence of chipping. Specifically, the controller 90 positions the cutting blade 43 on an extension line of the planned dividing line 3 extending in the <100> direction, and positions the lower end portion of the cutting blade 43 at a depth that exceeds the back surface 1b of the substrate 1. Then, the controller 90 rotates and vibrates the cutting blade 43 while supplying a cutting liquid to the cutting blade 43, and moves the chuck table 30 along the X-axis direction. When cutting is performed at once in the <100> direction, the feed speed of the cutting blade 43 relative to the substrate 1 needs to be sufficiently slow, for example, 1 mm/s, which lengthens the cutting time.

In the production method of the chips 7 according to the present embodiment, when the cutting blade 43 cuts the substrate 1 along the planned dividing line 3 extending in the <100> direction, the cutting groove forming step S2 and the first dividing step S3 are performed to cut the substrate 1 in stages. In the first dividing step S3, since the uncut portion 1e is cut after the cutting groove 1c is formed in the cutting groove forming step S2, not only chipping is reduced, but also the cutting time can be shortened by increasing the feed speed of the cutting blade 43 in steps S2 and S3 as compared with a case where the substrate 1 is cut by the cutting blade 43 at once.

Although chipping is likely to occur when the substrate 1 is divided in the first dividing step S3, in the cutting groove forming step S2 performed in advance, since the cutting groove 1c is formed while the cutting blade 43 is vibrated at a vibration frequency in an ultrasonic band, the fractured layer 1d is formed in the uncut portion 1e, and cutting resistance in the first dividing step S3 can be reduced. Further, in the first dividing step S3, since the uncut portion 1e is cut by setting the rotation direction of the cutting blade 43 to the up-cut direction, chipping is further reduced.

As described above, according to the production method of the chips 7 of the present embodiment, even in a case of cutting the substrate 1 having cleavability that easily cleaves along a specific plane, chipping can be reduced and the cutting time can be shortened.

The depth of the cutting groove 1c formed in the cutting groove forming step S2 is preferably greater than half the thickness from the front surface 1a to the back surface 1b of the substrate 1. By providing the cutting groove 1c with a sufficient depth, the wobble of the cutting blade 43 in the cutting groove forming step S2 can be reduced, and the processing accuracy can be improved.

The feed speed of the cutting blade 43 in the cutting groove forming step S2 is preferably faster than the feed speed in the first dividing step S3. In the cutting groove forming step S2, the cutting groove 1c is formed but the substrate 1 is not divided, and thus chipping is relatively unlikely to occur. Therefore, the feed speed in the cutting groove forming step S2 can be increased, and thus the cutting time of the substrate 1 can be shortened. However, the feed speed of the cutting blade 43 in the cutting groove forming step S2 is not limited thereto, and may be equal to the feed speed in the first dividing step S3 or may be slower than the feed speed in the first dividing step S3.

In the first dividing step S3, it is preferable to cut the substrate 1 by rotating the cutting blade 43 without operating the ultrasonic vibrator 60. This can prevent the vibration of the cutting blade 43 from causing more damage than necessary to the crystal of the substrate 1. However, in the first dividing step S3, the controller 90 may rotate the cutting blade 43 while operating the ultrasonic vibrator 60.

Since chipping is unlikely to occur when cutting the substrate 1 in the <010> direction, the second dividing step S4 is performed without forming the cutting groove. That is, in the <010> direction of the substrate 1, the cutting groove forming step S2 is omitted, and the substrate 1 is cut and divided at once in the second dividing step S4. Thus, the cutting time of the substrate 1 can be shortened.

### Modification

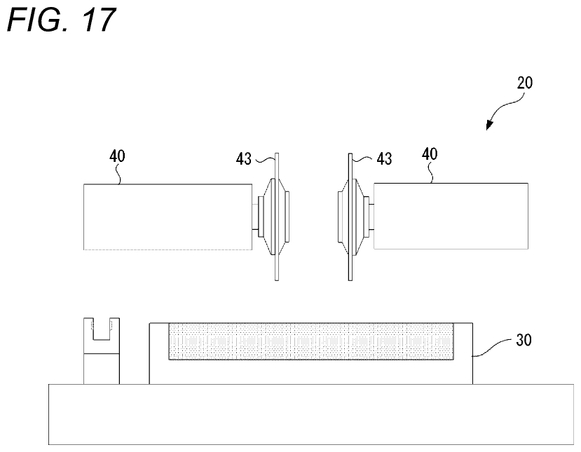

FIG. 16 is a top view of a cutting device 20 according to a modification in which a plurality of (here, two as an example) cutting units 40 are provided. FIG. 17 is a side view of the cutting device 20 according to the modification.

The cutting device 20 of the above embodiment includes one cutting unit 40 (cutting blade 43), and the cutting groove forming step S2, the first dividing step S3, and the second dividing step S4 are performed by the one cutting blade 43. When the cutting device 20 includes two cutting units 40 (cutting blades 43) as in the modification, the cutting groove forming step S2 and the first dividing step S3 (or the second dividing step S4) may be performed by different cutting blades 43. At this time, the thicknesses of the two cutting blades 43 may be the same or different.

Although the embodiment of the present disclosure have been described above with reference to the accompanying drawings, it is needless to say that the present disclosure is not limited to the embodiment. It is obvious that those skilled in the art may come up with various changes or modifications within the scope of the claims, and it is understood that these naturally fall within the technical scope of the present disclosure. In addition, components in the embodiment described above may be freely combined without departing from the gist of the disclosure.

For example, although the chip production method of the above embodiment is performed on the substrate 1 that is a gallium oxide substrate, the chip production method may be performed on a substrate that is made of a material other than gallium oxide and has cleavability that easily cleaves along a specific plane.

The present specification describes at least the following matters. Corresponding components and the like in the embodiment described above are shown in parentheses as an example, but the present disclosure is not limited thereto.
(1) A chip production method for producing a plurality of chips (chips 7) by dividing a substrate (substrate 1) having a first surface (front surface 1a) and a second surface (back surface 1b) opposite to the first surface along a plurality of planned dividing lines (planned dividing lines 3) set in a lattice pattern, the chip production method including:
   a holding step (holding step S1) of holding the second surface of the substrate by a holding table (chuck table 30) such that the first surface of the substrate is exposed;
   a cutting groove forming step (cutting groove forming step S2) of cutting the substrate along each of the planned dividing lines by rotating a cutting blade (cutting blade 43) in a down-cut direction from the first surface toward the second surface while vibrating the cutting blade at a vibration frequency in an ultrasonic band, thereby forming a cutting groove (cutting groove 1c) on the first surface that does not reach the second surface; and
   a first dividing step (first dividing step S3) of cutting an uncut portion (uncut portion 1e) of the planned dividing line where the cutting groove is formed by rotating the cutting blade in an up-cut direction from the second surface toward the first surface, after the cutting groove forming step.

When the first surface to the second surface of the substrate are cut at once with the cutting blade, it is necessary to reduce a cutting feed speed in order to reduce chipping on a cutting end surface. According to (1), since the substrate is cut in stages by performing the cutting groove forming step and the first dividing step, not only chipping is reduced, but also the cutting time can be shortened by increasing the feed speed of the cutting blade in each step as compared with a case where the substrate is cut by the cutting blade at once.

Although chipping is likely to occur in the first dividing step, since the cutting groove is formed while the cutting blade is vibrated at a vibration frequency of an ultrasonic band in the cutting groove forming step, a fractured layer is formed in the uncut portion, and cutting resistance in the first dividing step can be reduced. Further, in the first dividing step, the rotation direction of the cutting blade is set to the up-cut direction. With such a configuration, chipping in the first dividing step can be further reduced.

As a result, a chip production method capable of reducing the cutting time while reducing chipping is realized.
(2) The chip production method according to (1), in which
   in the cutting groove forming step and the first dividing step, the substrate is cut along the planned dividing line extending in a direction perpendicular to a cleavage plane of the substrate.

According to (2), even when a substrate having cleavability is cut, the cutting time can be shortened while reducing chipping.
(3) The chip production method according to (2), further including:
   a second dividing step (second dividing step S4) of cutting the substrate from the first surface to the second surface by rotating the cutting blade in the up-cut direction along the planned dividing line extending in a direction parallel to the cleavage plane of the substrate.

According to (3), since chipping is unlikely to occur when cutting in the direction parallel to the cleavage plane of the substrate, the substrate is divided without forming cutting grooves. Therefore, the cutting time can be shortened.
(4) The chip production method according to (1), in which
   the substrate is a gallium oxide substrate.

According to (4), it is possible to reduce the cutting time of a gallium oxide substrate having cleavability that easily cleaves along a specific plane while reducing chipping.
(5) The chip production method according to (4), in which
   the first surface of the substrate is a {001} plane, and
   in the cutting groove forming step and the first dividing step, cutting is performed along the planned dividing line extending in a <100> direction of the substrate.

According to (5), although chipping is likely to occur when cutting a gallium oxide substrate in the <100> direction, the cutting groove forming step and the first dividing step are performed along the <100> direction, and therefore, chipping can be reduced.
(6) The chip production method according to (5), further including:
   a second dividing step (second dividing step S4) of cutting the substrate from the first surface to the second surface by rotating the cutting blade in the up-cut direction along the planned dividing line extending in a <010> direction of the substrate.

According to (6), since chipping is unlikely to occur when cutting a gallium oxide substrate in the <010> direction, the substrate can be divided without forming cutting grooves. Therefore, the cutting time can be shortened.
(7) The chip production method according to any one of (1) to (6), in which
   a depth of the cutting groove formed in the cutting groove forming step is greater than half a thickness from the first surface to the second surface of the substrate.

According to (7), by providing the cutting groove with a sufficient depth, the wobble of the cutting blade in the cutting groove forming step can be reduced, and the processing accuracy can be improved.
(8) The chip production method according to any one of (1) to (7), in which
   a feed speed of the cutting blade in the cutting groove forming step is faster than a feed speed in the first dividing step.

According to (8), the cutting time of the substrate can be shortened by increasing the feed speed in the cutting groove forming step in which chipping is relatively unlikely to occur.
(9) A cutting device (cutting device 20) for producing a plurality of chips (chips 7) by dividing a substrate (substrate 1) having a first surface (front surface 1a) and a second surface (back surface 1b) opposite to the first surface along a plurality of planned dividing lines (planned dividing lines 3) set in a lattice pattern, the cutting device including:
   a holding table (chuck table 30) configured to hold the second surface of the substrate such that the first surface of the substrate is exposed;
   a cutting unit (cutting unit 40) including a cutting blade (cutting blade 43) configured to relatively move along the planned dividing lines to cut the substrate; and
   a controller (controller 90) configured to control the holding table and the cutting unit, in which
   the cutting unit further includes an ultrasonic vibrator (ultrasonic vibrator 60) capable of vibrating the cutting blade at a vibration frequency in an ultrasonic band, and
   the controller executes a process (cutting groove forming step S2 and first dividing step S3) of
      cutting the substrate along each of the planned dividing lines by rotating the cutting blade in a down-cut direction from the first surface toward the second surface while vibrating the cutting blade at a vibration frequency in an ultrasonic band, thereby forming a cutting groove (cutting groove 1c) on the first surface that does not reach the second surface, and
      cutting an uncut portion (uncut portion 1e) of the planned dividing line where the cutting groove is formed by rotating the cutting blade in an up-cut direction from the second surface toward the first surface, after the cutting groove is formed.

According to (9), similarly to the above (1), the cutting time can be shortened while reducing chipping.

### REFERENCE SIGNS LIST

1 substrate
1a front surface (first surface)
1b back surface (second surface)
1c cutting groove
1e uncut portion
3 planned dividing line
7 chip
20 cutting device
30 chuck table (holding table)
40 cutting unit
43 cutting blade
60 ultrasonic vibrator
90 controller
S1 holding step
S2 cutting groove forming step
S3 first dividing step
S4 second dividing step

What is claimed is:

1. A chip production method for producing a plurality of chips by dividing a substrate having a first surface and a second surface opposite to the first surface along a plurality of planned dividing lines set in a lattice pattern on the substrate, the chip production method comprising:
holding the second surface of the substrate by a holding table such that the first surface of the substrate is exposed;
cutting the substrate along each of the planned dividing lines by rotating a cutting blade in a down-cut direction from the first surface toward the second surface while vibrating the cutting blade at a vibration frequency in an ultrasonic band, thereby forming a cutting groove on the first surface that does not reach the second surface; and
cutting an uncut portion of the planned dividing line where the cutting groove is formed by rotating the cutting blade in an up-cut direction from the second surface toward the first surface, after the forming of the cutting groove.

2. The chip production method according to claim 1, wherein
in the forming of the cutting groove and the cutting of the uncut portion, the substrate is cut along the planned dividing line extending in a direction perpendicular to a cleavage plane of the substrate.

3. The chip production method according to claim 2, further comprising:
cutting the substrate from the first surface to the second surface by rotating the cutting blade in the up-cut direction along the planned dividing line extending in a direction parallel to the cleavage plane of the substrate.

4. The chip production method according to claim 1, wherein
the substrate is a gallium oxide substrate.

5. The chip production method according to claim 4, wherein
the first surface of the substrate is a {001} plane, and
in the forming of the cutting groove and the cutting of the uncut portion, cutting is performed along the planned dividing line extending in a <100> direction of the substrate.

6. The chip production method according to claim 5, further comprising:
cutting the substrate from the first surface to the second surface by rotating the cutting blade in the up-cut direction along the planned dividing line extending in a <010> direction of the substrate.

7. The chip production method according to claim 1, wherein
a depth of the cutting groove formed in the forming of the cutting groove is greater than half of a thickness, from the first surface to the second surface, of the substrate.

8. The chip production method according to claim 2, wherein
a depth of the cutting groove formed in the forming of the cutting groove is greater than half of a thickness, from the first surface to the second surface, of the substrate.

9. The chip production method according to claim 3, wherein
a depth of the cutting groove formed in the forming of the cutting groove is greater than half of a thickness, from the first surface to the second surface, of the substrate.

10. The chip production method according to claim 4, wherein
a depth of the cutting groove formed in the forming of the cutting groove is greater than half of a thickness, from the first surface to the second surface, of the substrate.

11. The chip production method according to claim 5, wherein
a depth of the cutting groove formed in the forming of the cutting groove is greater than half of a thickness, from the first surface to the second surface, of the substrate.

12. The chip production method according to claim 6, wherein
a depth of the cutting groove formed in the forming of the cutting groove is greater than half of a thickness, from the first surface to the second surface, of the substrate.

13. The chip production method according to claim 1, wherein
a feed speed of the cutting blade in the forming of the cutting groove is faster than a feed speed of the cutting blade in the cutting of the uncut portion.

14. The chip production method according to claim 2, wherein
a feed speed of the cutting blade in the forming of the cutting groove is faster than a feed speed of the cutting blade in the cutting of the uncut portion.

15. The chip production method according to claim 3, wherein
a feed speed of the cutting blade in the forming of the cutting groove is faster than a feed speed of the cutting blade in the cutting of the uncut portion.

16. The chip production method according to claim 4, wherein
a feed speed of the cutting blade in the forming of the cutting groove is faster than a feed speed of the cutting blade in the cutting of the uncut portion.

17. The chip production method according to claim 5, wherein
a feed speed of the cutting blade in the forming of the cutting groove is faster than a feed speed of the cutting blade in the cutting of the uncut portion.

18. The chip production method according to claim 6, wherein
a feed speed of the cutting blade in the forming of the cutting groove is faster than a feed speed of the cutting blade in the cutting of the uncut portion.

19. A cutting device for producing a plurality of chips by dividing a substrate having a first surface and a second surface opposite to the first surface along a plurality of planned dividing lines set in a lattice pattern on the substrate, the cutting device comprising:
a holding table configured to hold the second surface of the substrate such that the first surface of the substrate is exposed;
a cutting unit including a cutting blade configured to move the cutting blade relative to the substrate along the planned dividing lines to cut the substrate; and
a controller configured to control the holding table and the cutting unit, wherein
the cutting unit further includes an ultrasonic vibrator capable of vibrating the cutting blade at a vibration frequency in an ultrasonic band, and
the controller executes a process of
cutting the substrate along each of the planned dividing lines by rotating the cutting blade in a down-cut direction from the first surface toward the second surface while vibrating the cutting blade at a vibration frequency in an ultrasonic band, thereby forming a cutting groove on the first surface that does not reach the second surface, and
cutting an uncut portion of the planned dividing line where the cutting groove is formed by rotating the cutting blade in an up-cut direction from the second surface toward the first surface, after the cutting groove is formed.
